(19) United States
(12) Patent Application Publication
(10) Pub. No.: US 2006/0255372 A1
(43) Pub. Date: Nov. 16, 2006

(54) Color pixels with anti-blooming isolation and method of formation

(75) Inventors: Inna Patrick, Boise, ID (US); John Ladd, Boise, ID (US)

Correspondence Address: DICKSTEIN SHAPIRO LLP, 1825 EYE STREET NW, Washington, DC, 20006-5403, US

(73) Assignee: Micron Technology, Inc.

(21) Appl. No.: 11/129,462

(22) Filed: May 16, 2005

(51) Int. Cl. H01L 27/148

(52) U.S. Cl. 257/225

(57) ABSTRACT

Implant regions of a first conductivity type are formed under at least a portion of a first pixel sensor cell and of a second pixel cell to limit the depth of the photodiode collection/depletion region and limit the pixel's color response. To further reduce cross-talk between adjacent pixels and to decrease blooming, an anti-blooming isolation region of a second conductivity type is formed in the substrate and below the stop implant regions of the first conductivity type.

### FIELD OF THE INVENTION

The present invention relates to the field of semiconductor devices and, in particular, to high quantum efficiency CMOS image sensors having an anti-blooming structure.

### BACKGROUND OF THE INVENTION

Imagers typically consist of an array of pixel cells containing photosensors, where each pixel produces a signal corresponding to the intensity of light impinging on that element when an image is focused on the array. These signals may then be stored, for example, to display a corresponding image on a monitor or otherwise used to provide information about the optical image. The photosensors are typically phototransistors, photoconductors, photogates or photodiodes. The magnitude of the signal produced by each pixel, therefore, is proportional to the amount of light impinging on the photosensor.

To allow the photosensors to capture a color image, the photosensors must be able to separately detect red (R) photons, green (G) photons and blue (B) photons. Accordingly, each pixel must be sensitive only to one color or spectral band. For this, a color filter array (CFA) is typically placed in front of the pixels so that each pixel measures the light of the color of its associated filter.

Color imaging requires three pixel cells for the formation of a single color pixel. For example, a conventional color pixel sensor 50 is illustrated in FIG. 1 as a linear layout for convenience as including a red active pixel sensor cell 52, a blue active pixel sensor cell 54 and a green active pixel sensor cell 56, spaced apart on the semiconductor substrate 16 by isolation regions 19. Each of the red, blue and green active pixel sensor cells 52, 54, 56 have respective red, blue and green filters 53, 55, 57, which allow only red, blue and green photons, respectively, to pass through. In practice, the color pixels are typically arranged in a Bayer pattern pixel array in rows and columns, with one row of alternating green and blue pixels, and another row of alternating red and green pixels.

A brief description of the structural and functional elements of each of the red, blue and green active pixel sensor cells 52, 54, 56 is provided below. Each of the pixel sensor cells 52, 54, 56 is shown in part as a cross-sectional view of a semiconductor substrate 16, which may be a p-type silicon epitaxial layer 16 provided over a p-type substrate 51 and having a well of p-type material 20. An n+ type region 26 is formed as part of a photosensor formed as a photodiode with a p-type layer 53 above it, and laterally displaced from p-well 20. A transfer gate 28 is formed between the n+ type region 26 and a second n+ type region 30 formed in p-well 20. The n+regions 26 and 30 and transfer gate 28 form a charge transfer transistor 29 which is controlled by a transfer signal TX. The n+ region 30 is typically called a floating diffusion region. The n+ region 30 is also a storage node for receiving charge from the n+ type region 26 and for passing charge accumulated there at to the gate of a source follower transistor 36 described below.

A reset gate 32 is also formed adjacent and between the n+ type region 30 and another n+ region 34 which is also formed in p-well 20. The reset gate 32 and n+ regions 30 and 34 form a reset transistor 31 which is controlled by a reset signal RST. The n+ type region 34 is coupled to voltage source V_{aa pix}. The transfer and reset transistors 29, 31 are n-channel transistors as described in this implementation of a CMOS imager circuit in a p-well. As known in the art, it is also possible to implement a CMOS imager in an n-well, in which case each of the transistors would be p-channel transistors. It should also be noted that, while FIG. 1 shows the use of a transfer gate 28 and associated transistor 29, this structure is not required.

Each of the pixel sensor cells 52, 54, 56 also includes two additional n-channel transistors, a source follower transistor 36 and a row select transistor 38. Transistors 36, 38 are coupled in series, source to drain, with the source of transistor 36 also coupled to voltage source V_{aa pix} and the drain of transistor 38 coupled to a column line 39. The drain of the row select transistor 38 is connected via a conductor to the drains of similar row select transistors for other pixels in a given pixel column. Thus, the red, blue and green active pixel sensor cells 52, 54, 56 operate in a similar way, except that the information provided by each of the red, blue and green active pixel sensor cells 52, 54, 56 is limited by the intensities of the red, blue and green light, respectively.

One of the drawbacks of using a color pixel sensor, such as the color pixel sensor 50 of FIG. 1, is that the minority carriers in the blue pixel sensor cell 54, for example, are substantially more likely to be lost in recombination than the minority carriers formed in the red and green pixel sensor cells 52, 56. The difference in the recombination rates is due to the relatively shallow penetration depths of the blue photons, the higher majority carrier concentration that exists in the n+ region 30 than in the substrate 16, and the depth of the junction. For example, even though the average penetration of a blue photon in a CMOS photodiode is approximately 0.2 microns, a large number of blue photons fail to penetrate beyond the 0.1 micron junction. This way, a large amount of these photons are lost to recombinations and the blue cell response remains substantially below the red cell and green cell responses.

Another problem often associated with photodiodes is that of blooming. That is, under illumination, electrons can fill up an n-type region 26. Under saturation light conditions, the n-type region 26 can completely fill with electrons, and the electrons will then bloom to adjacent pixels. Blooming is undesirable because it can lead, for example, to the presence of a bright spot on the image.

The above-noted drawbacks of color photosensors have been addressed partially in the prior art. For example, U.S. application Ser. No. 10/648,378 to Rhodes et al., entitled Method of Forming Well for CMOS Imagers (filed Aug. 27, 2003), describes the formation of a well region that is totally masked from a photodiode region of a pixel sensor cell, improving therefore the charge transfer between the photodiode and a transistor gate. U.S. application Ser. No. 10/740,599 to Rhodes et al., entitled Image Sensor for reduced Dark Current (filed Dec. 22, 2003), addresses the reduction of dark current by proving a peripheral sidewall formed in a substrate region underlying a pixel array region, to separate the pixel array region from a peripheral circuitry region of an image sensor. U.S. Pat. No. 6,878,568 issued Apr. 12, 2005 to Rhodes et al. teaches a deep implanted region formed below a transistor array of a pixel sensor cell and adjacent a charge collection region of a photodiode.

An improved pixel sensor cell for use in an imager that exhibits improved color separation, reduced cross talk and blooming, as well as increased photodiode capacitance, is needed. A method of fabricating a pixel sensor cell exhibiting these improvements is also needed.

### SUMMARY OF THE INVENTION

In one aspect, the invention provides multiple implant regions of a first conductivity type formed below respective photosensors of an imager. A first implant region is formed under at least a portion of a first color photosensor to limit the depth of first collection/depletion in the substrate for the first color photosensor. A second implant region is formed under at least a portion of a second color photosensor to limit the depth of a second collection/depletion in the substrate for the second color photosensor. In an exemplary embodiment, the first and second color photosensors are blue and green, respectively, and the implants for each are at different depths.

To further reduce cross-talk between adjacent pixels and to decrease blooming, an anti-blooming region of a second conductivity type is formed in the substrate and below the multiple implant regions of the first conductivity type.

In another aspect, the invention provides a method of forming pixels having the implant regions and/or the anti-blooming region described above.

These and other features and advantages of the invention will be more apparent from the following detailed description that is provided in connection with the accompanying drawings and illustrated exemplary embodiments of the invention.

### BRIEF DESCRIPTION OF THE DRAWINGS

FIG. 1 is a cross-section view of an exemplary conventional CMOS image sensor pixel.

FIG. 2 is a schematic cross-sectional view of a row of CMOS image sensor pixels illustrating the fabrication of stop implant regions in accordance with a first embodiment of the present invention and at an initial stage of processing.

FIG. 3 is a schematic cross-sectional view of the row of CMOS image sensor pixels of FIG. 2 at a stage of processing subsequent to that shown in FIG. 2.

FIG. 4 is a schematic cross-sectional view of the row of CMOS image sensor pixels of FIG. 2 at a stage of processing subsequent to that shown in FIG. 3.

FIG. 5 is a schematic cross-sectional view of the row of CMOS image sensor pixels of FIG. 2 at a stage of processing subsequent to that shown in FIG. 2.

FIG. 6 is a schematic cross-sectional view of the row of CMOS image sensor pixels of FIG. 2 at a stage of processing subsequent to that shown in FIG. 5.

FIG. 7 is a schematic cross-sectional view of a row of CMOS image sensor pixels illustrating the fabrication of stop implant regions and of an anti-blooming region in accordance with the present invention and at an initial stage of processing.

FIG. 8 is a schematic cross-sectional view of the row of CMOS image sensor pixels of FIG. 7 at a stage of processing subsequent to that shown in FIG. 7.

FIG. 9 is a schematic cross-sectional view of the row of CMOS image sensor pixels of FIG. 7 at a stage of processing subsequent to that shown in FIG. 8.

FIG. 10 illustrates a schematic diagram of a computer processor system incorporating a row of CMOS image sensor pixels fabricated according to the present invention.

### DETAILED DESCRIPTION OF THE INVENTION

In the following detailed description, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that other embodiments may be utilized, and that structural, logical and electrical changes may be made without departing from the spirit and scope of the present invention.

The terms “wafer” and “substrate” are to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” or “substrate” in the following description, previous process steps may have been utilized to form regions or junctions in or over the base semiconductor structure or foundation. In addition, the semiconductor need not be silicon-based, but could be based on silicon-germanium, silicon-on-insulator, silicon-on-sapphire, germanium, or gallium arsenide, or other semiconductor materials.

The term “pixel” or “pixel cell” refers to a picture element unit cell containing a photosensor and transistors for converting electromagnetic radiation to an electrical signal. For purposes of illustration, portions of representative pixels are illustrated in the figures and description herein and, typically, fabrication of all imager pixels in an imager array will proceed simultaneously in a similar fashion.

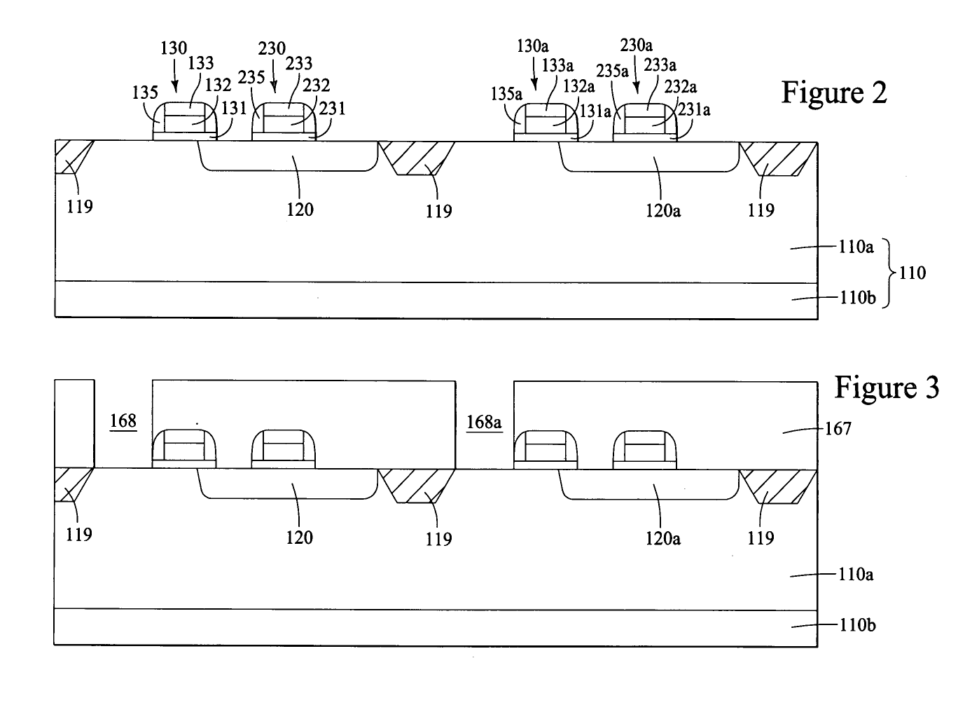

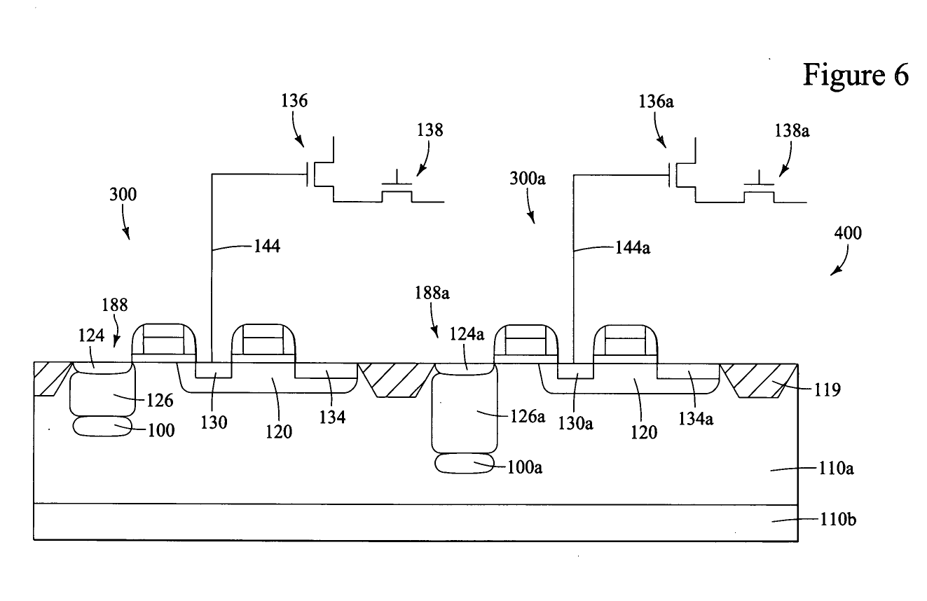

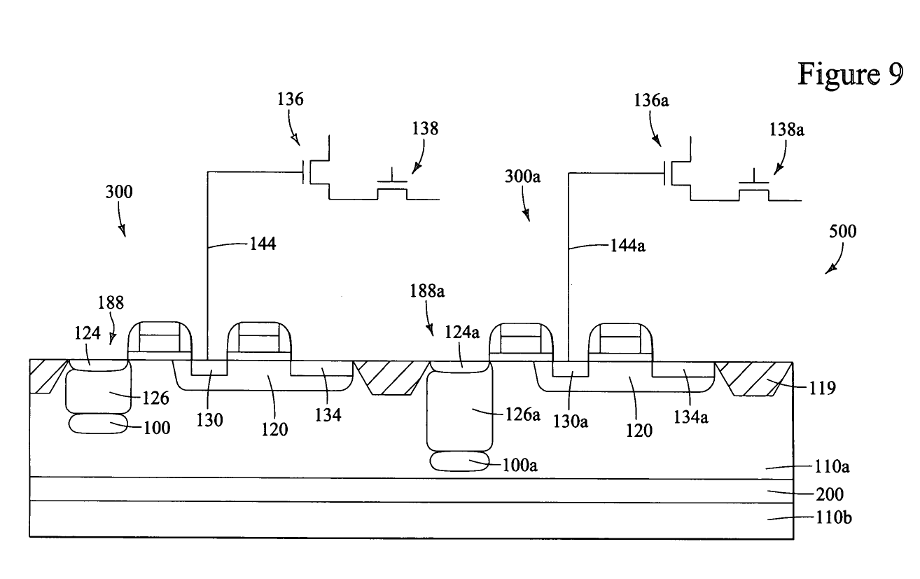

Referring now to the drawings, where like elements are designated by like reference numerals, FIGS. 2-9 illustrate exemplary embodiments of methods of forming implant regions 100, 100a of exemplary four-transistor (4T) color pixels 300, 300a (FIGS. 6 and 9), respectively, of a column/row of a color pixel cell group 400, 500. referring to FIGS. 6 and 9, as explained in more detail below, the implant regions 100, 100a are of a first conductivity type and are located below the surface of substrate 110 and below charge collection regions 126, 126a of photosensors formed as photodiodes 188, 188a, of different color pixel sensor cells 300, 300a (FIGS. 6 and 9). In one embodiment, an anti-blooming region 200 (FIG. 9) of a second conductivity type is formed in the substrate and below the multiple implant regions 100, 100a, to further reduce cross-talk between adjacent pixels and to decrease blooming.

It should be noted that, although the invention will be described below in connection with use in a four-transistor (4T) pixel cell, the invention also has applicability to any CMOS imager including, for example, a five-transistor (5T) pixel cell, a six-transistor (6T) pixel cell, or a three-transistor (3T) pixel cell, among others. The invention also has application to other solid state photosensor arrays and is not limited to CMOS photosensor arrays. In addition, although the invention will be described below with reference to implant regions 100, 100a formed below photosensors of exemplary blue and green pixel sensor cells 300, 300a, the invention is not limited to this illustrative embodiment, and has applicability to any color pixel sensor cell or to a combination of such color pixel sensor cells. Further, although the invention is described with reference to red, blue and green photosensors, the invention is not limited to this combination of photosensor colors and it can be used with YCMK color pixel arrays, and others as well.

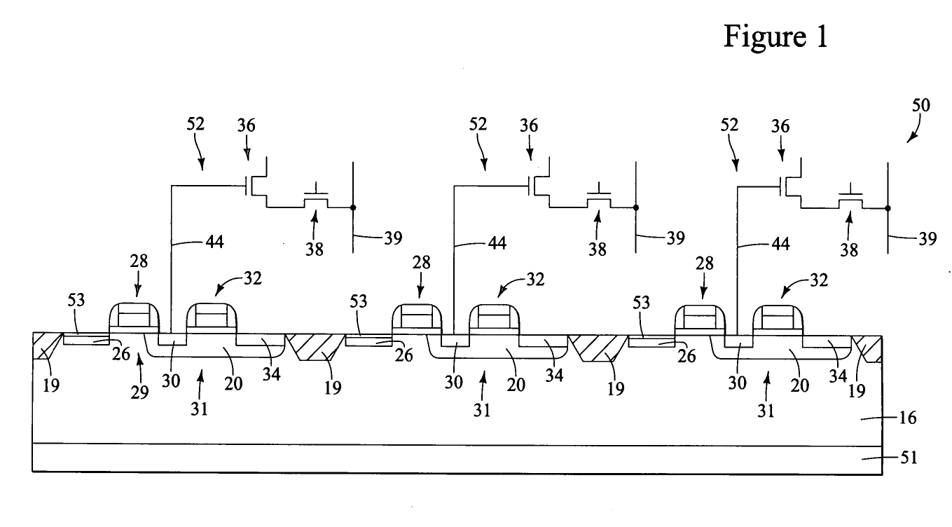

FIG. 2 illustrates a substrate 110 along a cross-sectional view which is the same view as in FIG. 1. For exemplary purposes, FIGS. 2-9 illustrate the substrate 110 as comprising an epitaxial layer supported by a base semiconductor. If a p+ epitaxial substrate layer is desired, a p-type epitaxial (epi) layer 110a (FIG. 2) is formed over a highly doped P+ substrate 110b, as illustrated in FIG. 2. The p-type epitaxial layer 110a may be formed to a thickness of about 2 microns to about 12 microns, more preferably of about 3 microns to about 7 microns, most preferably of about 3 microns. The p-type epitaxial layer 110a may have a dopant concentration in the range of about 1×10¹⁴ to about 5×10¹⁶ atoms per cm³, more preferably of about 5×10¹⁴ to about 5×10¹⁵ atoms per cm³.

FIG. 2 also illustrates conventional field oxide regions 119, often referred to as trench isolation regions, formed in the p-type epitaxial layer 110a. The field oxide regions 119 are formed using a conventional STI process and are typically formed by etching a trench in the substrate via a directional etching process, such as Reactive Ion Etching (RIE), or etching with a preferential anisotropic etchant used to etch into the substrate.

The trenches are then filled with an insulating material, for example, silicon dioxide, silicon nitride, ON (oxide-nitride), NO (nitride-oxide), or ONO (oxide-nitride-oxide). The insulating materials may be formed by various chemical vapor deposition (CVD) techniques such as low pressure chemical vapor deposition (LPCVD), high density plasma (HDP) deposition, or any other suitable method for depositing an insulating material within a trench. After the trenches are filled with an insulating material, a planarizing process such as chemical mechanical polishing is used to planarize the structure.

Multi-layered transfer gate stacks 130, 130a and reset gate stacks 230, 230a, each corresponding to exemplary four-transistor (4T) blue and green pixel sensor cells, respectively, are formed over the p-type epitaxial layer 110a after the STI trenches are formed and filled. Although FIG. 2 illustrates gate stacks that correspond to one blue and one green pixel cell, respectively, the invention is not limited to this illustrative embodiment, and contemplates a plurality of alternating gate stacks that correspond to a plurality of alternating color pixel cells.

The elements of the gate stack 130 are similar to those of the gate stack 130a, 230 and 230a, and thus, for simplicity, a description of only the elements of the gate stack 130 is provided below. The transfer gate stack 130 comprises a first gate oxide layer 131 of grown or deposited silicon oxide on the p-type epitaxial layer 110a, a conductive layer 132 of doped polysilicon or other suitable conductor material, and a second insulating layer 133, which may be formed of, for example, silicon oxide (silicon dioxide), nitride (silicon nitride), oxynitride (silicon oxynitride), ON (oxide-nitride), NO (nitride-oxide), or ONO (oxide-nitride-oxide). The first and second insulating layers 131, 133 and the conductive layer 132 may be formed by conventional deposition and etching methods, for example, blanket chemical vapor deposition (CVD) or plasma enhanced chemical vapor deposition (PECVD), followed by a patterned etch, among many others. Sidewall spacers 135, 235, 135a and 235a are formed by depositing and etching an insulating layer. The order of these process steps may be varied as is required or convenient for a particular process flow.

FIG. 2 further illustrates an optional p-type implanted well 120 located below the gate stacks 130 130a and 230 and 230a, respectively. The p-type implanted well 120 may be formed by dopant implantation before or after the formation of gate stacks 130 130a, 230 and 230a.

Reference is now made to FIG. 3. Subsequent to the formation of the gate stacks 130, 130a, 230 and 230a, and of the optional p-type implanted well 120, a photoresist layer 167 is formed over the structure of FIG. 2 to a thickness of about 1,000 Angstroms to about 50,000 Angstroms. The photoresist layer 167 is patterned to obtain openings 168, 168a over the p-type epitaxial layer 110a where elements of the photosensors 188, 188a will be formed as described below.

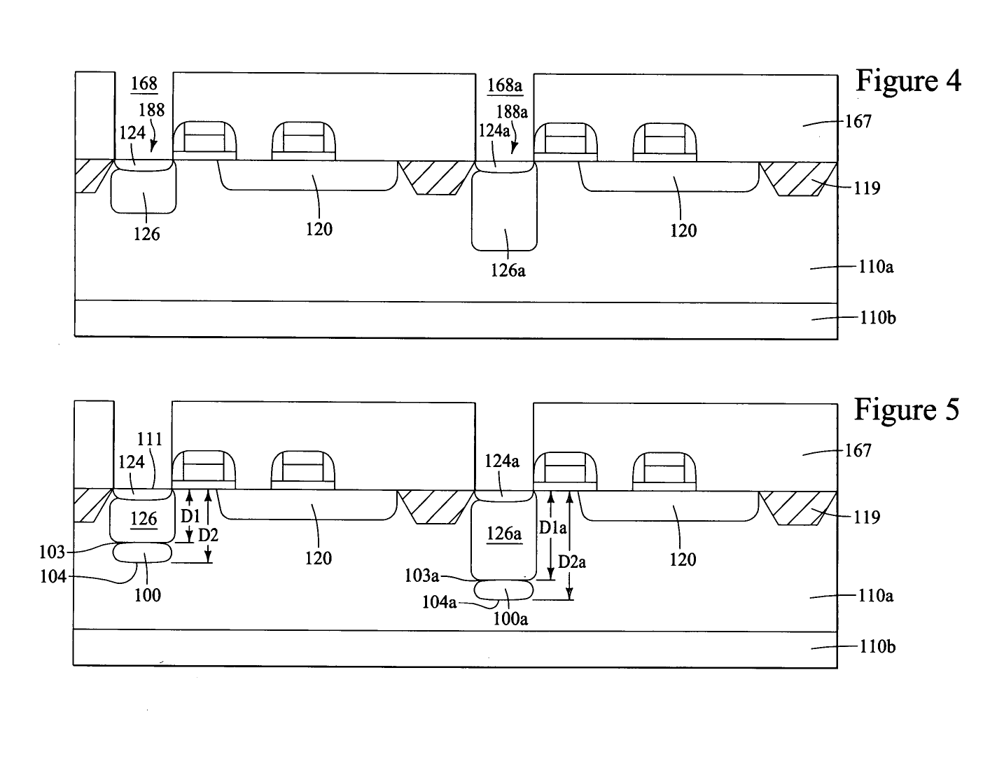

According to an exemplary embodiment of the invention, each of the photosensors 188, 188a is a p-n-p photodiode formed by regions 124, 124a, p-type epitaxial layer 110a, and regions 126, 126a, respectively. The n-type region 126, 126a (FIG. 4) is formed by implanting dopants of a second conductivity type, which for exemplary purposes is n-type, in the area of the substrate directly beneath the active areas of the adjacent blue and green pixel cells. The implanted n-doped region 126, 126a forms a photosensitive charge storage region for collecting photogenerated electrons. Ion implantation may be conducted by placing the substrate 110 in an ion implanter, and implanting appropriate n-type dopant ions into the substrate 110 at an energy of 20 keV to 1 MeV to form n-doped region 126, 126a. N-type dopants such as arsenic or phosphorous may be employed. The dopant concentration in the n-doped region 126, 126a (FIG. 4) is within the range of about 1×10¹⁵ to about 1×10¹⁸ atoms per cm³, and is preferably within the range of about 3×10¹⁶to about 3×10¹⁷ atoms per cm³. If desired, multiple implants may be used to tailor the profile of the n-doped region 126, 126a. The implants forming region 126, 126a may also be angled implants, formed by angling the direction of implants toward the gate stack 130, 130a.

Another dopant implantation with a dopant of a first conductivity type, which for exemplary purposes is p-type, is subsequently conducted so that p-type ions are implanted into the area of the substrate over the implanted n-type region 126, 126a, to form a p-type pinned surface layer 124, 124a of the now completed photodiode 188, 188a (FIG. 4).

Subsequent to the formation of the photodiode 188, 188a, and using the same patterned photoresist 167 as a mask, p-type ions are implanted through openings 168 and into areas of the p-type epitaxial layer 110a to form a first implant region 100 (or a blue stop implant region 100), as illustrated in FIG. 5. The first implant region 100 extends below surface 111 of the p-type epitaxial layer 110a, and is located below at least a portion of the implanted n-type region 126. The depth into the substrate 110 of upper margin 103, shown as depth D₁ (FIG. 5), of the first implant region 100 is of about 0.5 to about 1 microns, more preferably of about 0.6 micron. The depth into the substrate 110 of lower margin 104, shown as depth D₂ (FIG. 5), of the first implant region 100 is of about 0.6 to about 2 microns, more preferably of about 1 micron.

The first implant region 100 (FIG. 5) may be a P+ or a P− implanted region formed by conducting a dopant implantation to implant p-type ions, such as boron or indium, into area of the p-type epitaxial layer 110a. The ion implantation may be conducted at an energy of 50 keV to about 5 MeV, more preferably of about 100 keV to about 1 MeV. The implant dose in the first implant region 100 is within the range of about 5×10¹⁶ to about 5×10¹⁷ atoms per cm³. If desired, multiple implants may be used to tailor the profile of the first implant region 100 in the horizontal and vertical directions. In addition, the implant or the multiple implants forming the first implant region 100 may be angled or used in connection with at least one angled implant.

Subsequent to the formation of the first implant region 100, and preferably using the same patterned photoresist 167, p-type ions are implanted through opening 168a and into the p-type epitaxial layer 110a to form a second implant region 100a (or a green stop implant region 100a), as illustrated in FIG. 5. The second implant region 100 extends below surface 111 of the p-type epitaxial layer 110a, and is located below at least a portion of the implanted n-type region 126a. The depth into the substrate 110 of upper margin 103a, shown as depth D₁ₐ (FIG. 5), of the second implant region 100a is of about 1.5 to about 2.5 microns, more preferably of about 1.9 microns. The depth into the substrate 110 of lower margin 104a, shown as depth D₂ₐ (FIG. 5), of the second implant region 100a is of about 2 to about 4 microns, more preferably of about 2.5 microns.

The second implant region 100a (FIG. 5) may be a P+ or a P− implanted region formed by conducting a dopant implantation to implant p-type ions, such as boron or indium, into area of the p-type epitaxial layer 110a. The implant dose in the second implant region 100a is within the range of about 5×10⁶ to about 5×10¹⁷ atoms per cm³. If desired, multiple implants may be used to tailor the profile of the second implant region 100a in both the vertical or horizontal direction. In addition, the implant or the multiple implants forming the second implant region 100a may be angled or used in connection with at least one angled implant.

Subsequent to the formation of the second implant region 100a shown in FIG. 5, the patterned photoresist 167 is removed by conventional techniques, such as oxygen plasma for example. The remaining devices of the four-transistor (4T) pixel cell 300, 300a, including the source follower transistor 136, 136a and row select transistor 138, 138a shown in FIG. 1 as associated with respective gates and source/drain regions on either sides of the gates, are formed by well-known methods. The resulting structure is depicted in FIG. 6.

Although the embodiment above has been described with reference to the formation of the first implant region 100, employing a first resist mask, followed by the formation of the second implant region 100a employing the same first resist mask, the invention is not limited to this embodiment. Accordingly, the invention also contemplates the formation of the second implant region 100a first, followed by the subsequent formation of the first implant region 100, employing the same or different masks. In addition, the invention also contemplates embodiments in which the implant regions may be at least partially formed simultaneously. Further, the invention also contemplates embodiments in which the implant regions are first formed in the substrate, followed by the subsequent formation of the elements of the gate and/or photosensor structures, employing the same or different masks.

By providing the p-type first implant region 100 below the n-type region 126 of photodiode 188 of a first pixel sensor cell (for example, a blue pixel cell), as well as the p-type second implant region 100a below the n-type region 126a of photodiode 188a of a second pixel sensor cell (for example, a green pixel cell), color separation of the photodiodes corresponding to individual pixel sensor cells is improved and cross-talk between adjacent pixel sensor cells is reduced. Color separated photodiodes allow, in turn, to use thinner color filter array (CFA) (which is typically placed in front of the pixels so that each pixel measures the light of the color of its associated filter) and increase the light transmission by the CFA.

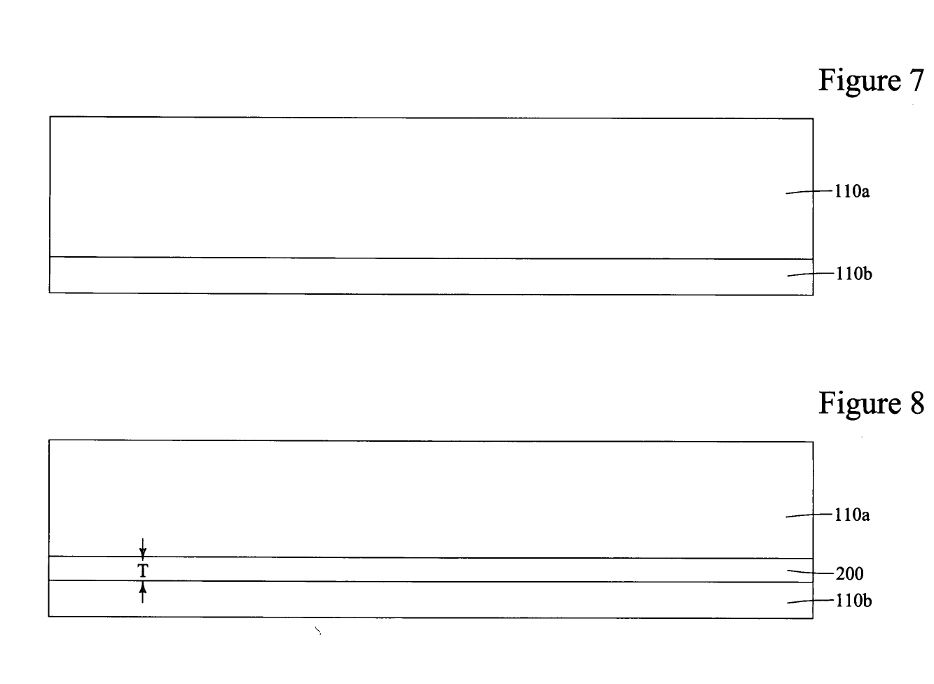

FIGS. 7-9 illustrate yet another embodiment according to which isolation region 200 (FIG. 9) (or anti-blooming isolation region 200) is formed in the substrate and optionally below the multiple implant regions 100, 100a, to further reduce cross-talk between adjacent pixels and to decrease blooming. In a preferred embodiment, the isolation region 200 has a conductivity type which is different from the conductivity type of the multiple implant regions 100, 100a (FIG. 6). Thus, in an exemplary embodiment of the present invention, the isolation region 200 is formed to an n-type conductivity corresponding to multiple implant regions 100, 100a of p-type conductivity.

Although the embodiment below will be described with reference to the formation of the isolation region 200 in connection with the multiple implant regions 100, 100a, the invention is not limited to this embodiment and contemplates the formation of the isolation region 200 without the multiple implant regions 100, 100a.

The isolation region 200 illustrated in FIG. 8 may be in the form of a stripe-like or grid-like implanted region under alternate pixel rows where the pixels of the row have, for example, alternating blue and green pixels. The isolation region 200 may be formed by conducting a blanket implantation with a dopant of the second conductivity type, which for exemplary purposes is n-type, to implant ions in the area of the substrate directly above the base substrate 110b of FIG. 7 and to form the anti-blooming isolation region 200, as illustrated in FIG. 8. N-type dopants such as arsenic, antimony, or phosphorous may be blanket implanted into the substrate 110. The dopant concentration in the n-type anti-blooming isolation region 200 is within the range of about 1×10¹⁵ to about 1×10¹⁸ atoms per cm³, and is preferably within the range of about 3×10¹⁶ to about 3×10¹⁷ atoms per cm³. If desired, multiple implants may be used to tailor the profile of the anti-blooming isolation region 200. The thickness T (FIG. 8) of the isolation region 200 is of about 0.5 to 2 microns, more preferably of about 0.75 microns.

In a preferred embodiment, the anti-blooming isolation region 200 may be connected to Vaa (positive power supply) outside the imager array, via, for example, N well and N+ diffusions, to bias the anti-blooming isolation region 200 positively and, therefore, to allow it to drain excess charge during anti-blooming operation.

Subsequent to the formation of the anti-blooming isolation region 200, all elements of the blue and green photosensors formed as blue and green photodiodes 188, 188a, and of the implanted regions 100, 100a of pixel sensor cells 300, 300a of color pixel cell group 500, are formed by the steps described above and illustrated in conjunction with FIGS. 2-6.

The p-type implant regions 100, 100a located adjacent and below the n-type region 126, 126a, and the n-type anti-blooming isolation region 200 located below the p-type stop implant regions 100, 100a act, as a reflective barrier to electrons generated by light in the n-doped regions 126, 126a of the p-n-p photodiodes 188, 188a. When light radiation in the form of photons strikes the photosite regions 126, 126a, photo-energy is converted to electrons which are stored in the n-doped region 126, 126a. The absorption of light creates electron-hole pairs. For the case of an n-doped photosite in a p-well or a p-type epitaxial layer, it is the electrons that are stored. For the case of a p-doped photosite in an n-well, it is the holes that are stored. Thus, in the exemplary embodiment described above having n-channel devices formed in the p-type epitaxial layer 110a, the carriers stored in the n-doped photosite region 126, 126a are electrons. The p-type implant regions 100, 100a of the blue and green pixels and the n-type anti-blooming isolation region 200 located below these implanted regions act as stop regions that reduce carrier loss to the substrate 110, by forming a concentration gradient that modifies the silicon potential and serves to reflect electrons back towards the n-doped photosite region 126, 126a, thereby reducing cross-talk between adjacent blue and green pixel sensor cells of a row or column. The n-type anti-blooming isolation region 200 also attracts the stray electrons generated or available in the bulk below it, and carries them away from photosite regions 126, 126a to the power supply.

The remaining devices of the pixel sensor cell 300, 300a, including the reset transistor, the source follower transistor and row select transistor shown in FIG. 1 as associated with respective gates and source/drain regions on either sides of the gates, are also formed by well-known methods. Conventional processing steps may be also employed to form contacts and wiring to connect gate lines and other connections in the pixel cell 300, 300a. For example, the entire surface may be covered with a passivation layer of, e.g., silicon dioxide, BSG, PSG, or BPSG, which is CMP planarized and etched to provide contact holes, which are then metallized to provide contacts to the reset gate, transfer gate and other pixel gate structures, as needed. Conventional multiple layers of conductors and insulators to other circuit structures may also be used to interconnect the structures of the pixel sensor cell.

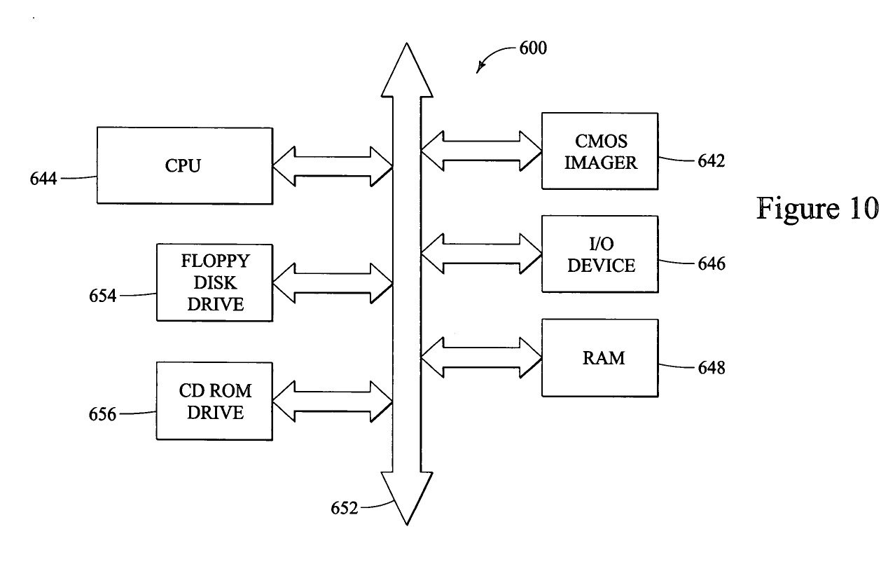

A typical processor based system 600, which has a connected CMOS imager 642 having pixel arrays constructed according to the invention is illustrated in FIG. 10. A processor based system is exemplary of a system having digital circuits which could include CMOS image sensors. Without being limiting, such a system could include a computer system, camera system, scanner, machine vision, vehicle navigation, video phone, surveillance system, auto focus system, star tracker system, motion detection system, stabilization system or other image processing system, all of which can utilize the present invention.

A processor based system, such as a camera system, for example generally comprises a central processing unit (CPU) 644, for example, a microprocessor, that communicates with an input/output (I/O) device 646 over a bus 652. The CMOS image sensor 642 also communicates with the system over bus 652. The computer system 600 also includes random access memory (RAM) 648, and, in the case of a computer system may include peripheral devices such as a floppy disk drive 654, and a compact disk (CD) ROM drive 656 or a flash memory card 657 which also communicate with CPU 644 over the bus 652. It may also be desirable to integrate the processor 654, CMOS image sensor 642 and memory 648 on a single IC chip.

Although the above embodiments have been described with reference to the formation of photosensors as p-n-p photodiodes of adjacent blue and green pixel cells, such as the p-n-p photodiode as photosensor 188, 188a (FIGS. 6 and 9) having n-type charge collection regions 126, 126a formed adjacent and above p-type stop implant regions 100, 100a, it must be understood that the invention is not limited to the described embodiments. Accordingly, the invention has equal applicability to other photosensors including photogates, photoconductors, photoconversion and other photosensors as well as n-p-n photodiode photosensors comprising comprising p-type charge collection regions formed adjacent n-type stop implant regions. Of course, the dopant and conductivity type of all structures will change accordingly, with the transfer gate corresponding to a PMOS transistor. Further, although the embodiments of the present invention have been described above with reference to a p-n-p photodiode, the invention also has applicability to n-p or p-n photodiodes.

In addition and as noted above, although the invention has been described with reference to the formation of only one anti-blooming region 200 running below the stop implant regions and the charge collection regions of photosensitive elements of adjacent pixel sensor cells, the invention also contemplates the formation of a multitude of such stripe implant regions located under various pixel rows on the substrate. Further, although the invention has been described above with reference to a transfer gate of a transfer transistor connection for use in a four-transistor (4T) pixel cell, the invention also has applicability to a five-transistor (5T) pixel cell, a six-transistor (6T) pixel cell, or a three-transistor (3T) cell, among others.

The above description and drawings are only to be considered illustrative of exemplary embodiments, which achieve the features and advantages of the invention. Modification and substitutions to specific process conditions and structures can be made without departing from the spirit and scope of the invention. Accordingly, the invention is not to be considered as being limited by the foregoing description and drawings, but is only limited by the scope of the appended claims.

What is claimed as new and desired to be protected by Letters Patent of the United States is:

1. An imaging device, comprising:
a substrate of a first conductivity type;
at least first and second photosensors formed over said substrate, each having respective regions of a second conductivity type for accumulating charges corresponding to a different respective wavelength of light; and
at least a first and second doped regions of said first conductivity type below said regions of said first and second photosensors, at least one of said first and second doped regions being at a different depth from another of said first and second doped regions.

2. The imaging device of claim 1 further comprising an implanted region of said second conductivity type located below said first and second doped regions.

3. The imaging device of claim 2, wherein said implanted region has a thickness of about 0.5 to about 2 microns.

4. The imaging device of claim 3, wherein said implanted region has a thickness of about 0.75 microns.

5. The imaging device of claim 2, wherein said implanted region is electrically connected to a terminal for receiving a source voltage.

6. The imaging device of claim 2, wherein said implanted region is formed in an epitaxial layer of said substrate, the upper margin of said implanted region extending below an upper surface of said epitaxial layer by about 2 to about 3 microns.

7. The imaging device of claim 1, wherein said first photosensor and associated first doped region are arranged to receive a blue wavelength of light, and wherein said second photosensor and associated second doped region are arranged to receive a green wavelength of light.

8. The imaging device of claim 1, wherein said first and second photosensors collect charges for blue and green wavelengths, respectively.

9. The imaging device of claim 1, wherein said first and second doped region are provided in an epitaxial layer of said substrate.

10. The imaging device of claim 9, wherein an upper margin of said first doped region extends below an upper surface of said epitaxial layer to a first depth of about 0.5 to about 1 microns, and wherein a lower said first doped region extends below said upper surface of said epitaxial layer to a second depth of about 0.6 to about 2 microns.

11. The imaging device of claim 9, wherein an upper margin of said second doped region extends below an upper surface of said epitaxial layer to a first depth of about 1.5 to about 2.5 microns, and wherein a lower said first doped region extends below said upper surface of said epitaxial layer to a second depth of about 2 to about 4 microns.

12. The imaging device of claim 9, wherein said epitaxial layer has a thickness of about 2 to about 12 microns.

13. The imaging device of claim 1, wherein said first doped region has a dopant concentration of about 5×10¹⁶ to about 5×10¹⁷ atoms per cm³.

14. The imaging device of claim 1, wherein said second doped region has a dopant concentration of about 5×10¹⁶ to about 5×10¹⁷ atoms per cm³.

15. The imaging device of claim 1, wherein said photosensor is a photodiode.

16. The imaging device of claim 15, wherein said photodiode is a p-n-p photodiode.

17. The imaging device of claim 15, wherein said photodiode is an n-p-n photodiode.

18. The imaging device of claim 1, wherein said imaging device is a CMOS imager.

19. An imaging device, comprising:
a substrate of a first conductivity type;
a first photosensor comprising a first charge collection region of a second conductivity type provided in said substrate, for sensing a first color wavelength;
a second photosensor comprising a second charge collection region of said second conductivity type provided in said substrate, for sensing a second color wavelength;
a first doped region of said first conductivity type extending below at least a portion of said first charge collection region;
a second doped region of said first conductivity type extending below at least a portion of said second charge collection region; and
an implanted region of said second conductivity type extending below said first and second doped regions.

20. The imaging device of claim 19, wherein said first charge collection region and associated first doped region are arranged to receive a blue wavelength of light, and wherein said second charge collection region and associated second doped region are arranged to receive a green wavelength of light.

21. The imaging device of claim 20, wherein said first charge collection region extends below an upper surface of said substrate to a depth of about 0.2 to about 0.8 microns.

22. The imaging device of claim 21, wherein said first charge collection region extends below said upper surface of said substrate to a depth of about 0.6 microns.

23. The imaging device of claim 20, wherein said second charge collection region extends below an upper surface of said substrate to a depth of about 1.5 to about 2.5 microns.

24. The imaging device of claim 23, wherein said second charge collection region extends below said upper surface of said substrate to a depth of about 1.9 microns.

25. The imaging device of claim 19, wherein said implanted region has a thickness of about 0.5 to about 2 microns.

26. The imaging device of claim 25, wherein said implanted region has a thickness of about 0.75 microns.

27. The imaging device of claim 19, wherein said imaging device is a CMOS imager.

28. An imager comprising:
a substrate having an epitaxial layer of a first conductivity type;
an array of pixel sensor cells formed in said epitaxial layer, said array comprising at least one row of alternating blue and green pixels, comprising:
a plurality of first and second photosensors formed in said epitaxial layer for sensing respective blue and green color wavelengths;
a plurality of first and second stop implant regions of said first conductivity type provided below respective first and second photosensors, said first and second stop implant regions having substantially different depths in said substrate and being displaced laterally from each other;
an implanted region of a second conductivity type located below said plurality of first and second stop implant region; and
a circuit electrically connected to receive and process output signals from said array.

29. The imager of claim 28, wherein said photosensor is a photodiode.

30. The imager of claim 28, wherein an upper surface of said first stop implant region extends below an upper surface of said epitaxial layer to a first depth of about 0.5 to about 1 microns, and wherein a lower surface of said first stop implant region extends below said upper surface of said epitaxial layer to a second depth of about 0.6 to about 2 microns.

31. The imager of claim 28, wherein an upper surface of said second stop implant region extends below an upper surface of said epitaxial layer to a first depth of about 1.5 to about 2.5 microns, and wherein a lower surface of said second stop implant region extends below said upper surface of said epitaxial layer to a second depth of about 2 to about 4 microns.

32. The imager of claim 28, wherein said epitaxial layer has a thickness of about 2 to about 12 microns.

33. The imager of claim 28, wherein said first stop implant region has a dopant concentration of about 5×10¹⁶ to about 5×10¹⁷ atoms per cm³.

34. The imager of claim 28, wherein said second stop implant region has a dopant concentration of about 5×10¹⁶ to about 5×10¹⁷ atoms per cm³.

35. The imager of claim 28, wherein said pixel sensor cell is a 3T pixel cell, a 4T pixel cell or a 5T pixel cell.

36. An imager system comprising:
(i) a processor; and
(ii) an imaging device coupled to said processor, said imaging device comprising:
a plurality of gate stacks formed over a substrate of a first conductivity type;
a plurality of photosensitive regions of a second conductivity type formed in said substrate for receiving photocharges corresponding to a particular wavelength; and
a plurality of doped regions of said first conductivity type formed in said substrate and below and in contact with each of the plurality of photosensitive regions, at least one of said plurality of doped regions having a different depth from an adjacent doped region.

37. The system of claim 36, further comprising an implanted region of said second conductivity type located below said plurality of doped regions.

38. The system of claim 37, wherein said implanted region has a thickness of about 0.75 microns.

39. The system of claim 36, wherein at least one of said doped regions has a dopant concentration of about 5×10¹⁶ to about 5×10¹⁷ atoms per cm³.

40. The system of claim 36, wherein at least one of said doped regions has a dopant concentration of about 5×10¹⁶ to about 5×10¹⁷ atoms per cm³.

41. The system of claim 36, wherein said plurality of photosensitive regions correspond to a plurality of photodiodes.

42. The system of claim 36, wherein said imager is a CMOS imager.

43. A method of forming photosensors for an imaging device,
said method comprising the steps of:
forming at least first and second photosensors having respective charge collection regions of a first conductivity type in a substrate, said substrate having a second conductivity type; and
forming at least first and second doped regions of said second conductivity type below respective first and second charge collection regions, said first and second doped regions being formed at different depths in said substrate.

44. The method of claim 43, further comprising forming an implanted region of said first conductivity type below said first and second doped regions.

45. The method of claim 43, wherein said first and second doped regions are formed by ion implantation.

46. The method of claim 43, wherein said first and second doped regions are formed sequentially.

47. The method of claim 43, wherein said first and second doped regions are formed subsequent to the formation of said first and second charge collection regions.

48. The method of claim 43, wherein said first and second doped regions are formed prior to the formation of said first and second charge collection regions.

49. A method of forming a color pixel cell for an imaging
device, said method comprising the steps of:
providing an epitaxial layer of a first conductivity type in a substrate;
forming a first plurality of charge collection regions of a second conductivity type in said epitaxial layer, said first plurality of charge collection regions accumulating charges corresponding to a first wavelength of light;
forming a second plurality of charge collection regions of said second conductivity type in said epitaxial layer, said second plurality of charge collection regions accumulating charges corresponding to a second wavelength of light;
forming a first plurality of doped regions of said first conductivity type in said epitaxial layer and below each of said first plurality of charge collection regions;
forming a second plurality of doped regions of said first conductivity type in said epitaxial layer and below each of said second plurality of charge collection regions; and
forming an implanted region of said second conductivity type below said first and second plurality of doped regions.

50. The method of claim 49, further comprising:
forming a plurality of photosensors on an upper surface of each of said charge collection regions for controlling the collection of charge therein; and
forming a plurality of floating diffusion regions of said second conductivity type in said epitaxial layer for receiving charges transferred from said charge collection regions.

51. The method of claim 50, wherein one of said first plurality of doped regions is formed at a first depth in said epitaxial layer.

52. The method of claim 51, wherein one of said second plurality of doped regions is formed at a second depth in said epitaxial layer, said second depth being greater than said first depth.

53. The method of claim 50, wherein one of said first plurality of doped regions corresponds to a blue pixel cell, and wherein one of said second plurality of doped regions corresponds to a green pixel cell.

54. The method of claim 49, wherein said first conductivity type is n-type, and said second conductivity type is p-type.

55. The method of claim 49, wherein said photosensitive regions correspond to photosensors.

56. The method of claim 55, wherein at least one of said photosensors is a photodiode.

57. A method of forming a pixel array for an imaging device,
said method comprising the steps of:
forming a plurality of alternating blue and green pixel sensor cells in a substrate of a first conductivity type, wherein each blue and green pixel sensor cell has a charge collection region of a second conductivity type and a floating diffusion region of a second conductivity type;
forming a first doped region of said first conductivity type below and in contact with each of said charge collection regions of said blue pixel sensor cells;
forming a second doped region of said first conductivity type below and in contact with each of said charge collection regions of said green pixel sensor cells; and
forming an implanted region of said second conductivity type below said first and second doped regions.

58. The method of claim 57, wherein said first doped region is formed by implantation and has a dopant concentration of about 5×10¹⁶ to about 5×10¹⁷ atoms per cm³.

59. The method of claim 57, wherein said second doped region is formed by implantation and has a dopant concentration of about 5×10¹⁶to about 5×10¹⁷ atoms per cm³.

60. The method of claim 57, wherein said implanted region is formed by blanket implantation.

61. The method of claim 57, wherein said implanted region is formed to a thickness of about 0.5 to about 2 microns.

62. The method of claim 57, wherein said first and second doped regions are formed sequentially.

63. The method of claim 57, wherein said first and second doped regions are formed simultaneously.
